(19) United States
(12) Patent Application Publication
(10) Pub. No.: US 2004/0216028 A1
(43) Pub. Date: Oct. 28, 2004

(54) Picture encoding apparatus and method, picture decoding apparatus and method, error correction encoding apparatus and method and error correction decoding apparatus and method

(75) Inventors: Takahiro Fukuhara, Kanagawa (JP); Seiji Kimura, Chiba (JP); Hitoshi Kiya, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: Hitoshi KIYA, Hachioji-shi (JP); Sony Corporation, Tokyo (JP)

(21) Appl. No.: 10/697,325

(22) Filed: Oct. 31, 2003

(30) Foreign Application Priority Data
Apr. 25, 2003 (JP) 2003-122438

(51) Int. Cl. H03M 13/00

(52) U.S. Cl. 714/776

(57) ABSTRACT

An error correction and encoding process is applied to a codestream being encoded in the process of encoding a picture in for example the JPEG-2000 system, or to an encoded codestream obtained by the encoding process, extremely readily and efficiently. For example, in generating an encoded codestream in accordance with the JPEG-2000 system, in a picture encoding apparatus, error correction encoding is applied to for example data of a header or to data of packets of an uppermost layer and a layer subjacent to the uppermost layer, to produce an inspection symbol, which is then embedded in its entirety in for example the lowermost layer. A picture decoding apparatus extracts this inspection symbol to perform error correction.

### BACKGROUND OF THE INVENTION

1. Field of the Invention

This invention relates to a picture encoding apparatus and method and an error correction apparatus and method for applying error correction and encoding to a codestream in the course of encoding in accordance with e.g. the JPEG-2000 system or to an codestream already encoded in accordance with the JPEG-2000 system. This invention also relates to a picture encoding apparatus and method and an error correction apparatus and method for carrying out error correction using an error correction code embedded in the encoded codestream.

This application claims priority of Japanese Patent Application No. 2003-122438 filed on Apr. 25, 2003, the entirety of which is incorporated by reference herein.

2. Description of Related Art

Among known typical picture compression systems, there is a JPEG (Joint Photographic Experts Group) system, standardized by ISO (International Standards Organization). This system uses discrete cosine transform (hereinafter referred to as DCT) and is able to provide satisfactorily encoded and decoded pictures when a larger amount of bits are allocated. However, if the number of bits for encoding is decreased to more than a certain extent, there occurs pronounced block distortion peculiar to DCT. The result is the pronounced subjective deterioration.

On the other hand, researches in systems for splitting the frequency spectrum of a picture into plural frequency bands by a filter composed of a high-pass filter and a low-pass filter, known as a filter bank, and for performing the encoding from one such frequency band to another, are progressing briskly. Of these systems, wavelet transform encoding is free from the drawback that block distortion becomes severe with higher compression, as in the case of the DCT, and hence is felt to be promising as a new technology which should take the place of the DCT.

The JPEG-2000 system, the international standardization for which has been completed in January 2001, uses a system which combines this wavelet transform with the high efficiency entropy encoding (bitplane based bit modeling and arithmetic coding) and has achieved marked improvement in the encoding efficiency as compared to JPEG (see for example the following Cited Reference 1).

[Cited Reference 1]

Japanese Laying-Open Patent Publication 2002-165098

Up to now, researches have been conducted in a technique, termed watermarking, in which data is introduced in a visually imperceptible form into a digital picture. This technique is divided into a type which is aimed to prevent secondary use of a picture or presumed illicit use of for example private authentication, and a type which is not. As for the state-of-the-art examples, already reported in Societies or Research Institutes, reference is made to H. Kobayashi, Y. Noguchi and H. Kiya, ‘Method for Embedding Binary Data in JPEG Codestring’, Shin-Gaku-Ron (D-11), vol.J83-D-11; No.6, pp.1469-1476, June 2000 and to H. Kiya, ‘Method for Embedding Binary Data in JPEG and MPEG Pictures’, Shin-Gaku-Ron (A), vol.J83-A, No.12, pp.1349-1356, December 2000.

These state-of-the-art examples are, however, presupposed on the use of DCT, so that these may be applied to the JPEG system or to the MPEG (Moving Picture Experts Group), but may not be applied to the JPEG-2000 system, exploiting the wavelet transform, as discussed above. The above-mentioned state-of-the-art examples also suffer from a problem that, since the embedding of the data affects the bitrate control at the time of the encoding, data embedding cannot be performed independently.

There has also been researched an error correction technique of embedding error correction codes in the transmitted data, in order that transmitted data can be reproduced satisfactorily on the receiving side, even if the transmitted data is partially lost on the communication channel. These error correction codes may be exemplified by for example the Reed-Solomon code, viterbi code and the turbo code.

Meanwhile, the JPEG-2000 standard provides for means mainly consisting in inserting marker codes and means by mode designation of the entropy coding, with a view to intensifying the resistance against errors. However, these standard error resistance functions are not sufficient to recover data lost by errors. Thus, in order to correct the errors completely, such a method is routinely used in which an encoded codestream for communication is protected with error correction codes.

This method however suffers from a drawback that only the codes with the predetermined error correction capability are usable, while it is not possible to change the error correction capability in meeting with the communication channel.

### SUMMARY OF THE INVENTION

In view of the above depicted state of the prior art, it is an object of the present invention to provide a picture encoding apparatus and method and an error correction encoding apparatus and method for readily efficiently applying error correction and encoding to a codestream in the course of encoding in accordance with e.g. the JPEG-2000 system or to an codestream obtained on encoding in accordance with the JPEG-2000 system, and a picture decoding apparatus and a picture decoding method and an error correction and decoding apparatus and method, for correcting the errors using the error correction codes embedded in the encoded codestream.

In one aspect, the present invention provides a picture encoding apparatus and method comprising applying arithmetic encoding to an input picture to generate an encoded codestream, splitting the encoded codestream into a plurality of layers, generating a plurality of packets from one layer to the next, applying error correction encoding to data of a header and/or packets of a predetermined one or more layers, and embedding an inspection symbol generated by the error correction encoding means in the packets of a predetermined lower layer.

In another aspect, the present invention provides a picture decoding apparatus and method in which an encoded codestream is supplied and decoded to restore an input picture. The encoded codestream is such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a packet of a predetermined lower layer. The apparatus and the method comprise analyzing the input encoded codestream, extracting the inspection symbol from the packet of the lower layer, applying error correction and decoding to data of the header and/or a packet or packets of one or more preset layers, using the inspection symbol, and decoding the encoded codestream following the error correction and decoding.

In a further aspect, the present invention provides a picture encoding apparatus and method comprising applying arithmetic coding to an input picture to generate an encoded codestream, splitting the encoded codestream into a plurality of layers, generating a plurality of packets from one layer to the next, applying error correction encoding to data of a header and/or a packet or packets of a predetermined one or more layers, and embedding an inspection symbol generated by the error correction encoding means in a main header or in a COM marker of a tile part header.

In a further aspect, the present invention provides a picture decoding apparatus and method in which an encoded codestream is supplied and decoded to restore an input picture. The encoded codestream is such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol, generated on this error correction coding, in a COM marker of a main header or a tile part header. The apparatus and the method comprise analyzing the input encoded codestream, extracting the inspection symbol from the COM marker, applying error correction and decoding to data of a header and/or a packet or packets of one or more preset layers, using the inspection symbol, and decoding the encoded codestream following the error correction and decoding.

In a further aspect, the present invention provides a picture encoding apparatus and method comprising filtering an input picture to generate a plurality of sub-bands splitting each sub-band to generate a plurality of code blocks, each being of a predetermined size, generating a plurality of bitplanes, from the most significant bit to the least significant bit, from one coefficient block to another, executing bit modeling from one bitplane to another, generating an encoding pass from one bitplane to another, executing arithmetic coding in the encoding pass generated by the encoding pass generating means to generate an encoded codestream, splitting the encoded codestream into a plurality of layers, generating a plurality of packets from one layer to another, applying error correction encoding to data of a header and/or a packet or packets of one or more layers, and embedding an inspection symbol generated by the error correction encoding means in a portion of a predetermined code block or in a newly added encoding pass.

In a further aspect, the present invention provides a picture decoding apparatus and method in which an encoded codestream is supplied and the input encoded codestream is decoded to restore an input picture. The encoded codestream such a one obtained on filtering an input picture in a picture encoding apparatus to generate a plurality of sub-bands, splitting the generated sub-bands to generate a plurality of code blocks each being of a predetermined size, generating a plurality of bitplanes from the most significant bit to the least significant bit, from one of the code blocks to another, performing bit modeling from one bitplane to another to generate a plurality of encoding passes, performing arithmetic coding in the generated encoding passes to generate an encoded codestream, splitting the encoded bitstream into a plurality of layers, generating a plurality of packets from one layer to another; applying error correction and encoding to data of a header or a packet or packets of preset one or more layers, and on embedding a generated inspection symbol in a portion of the preset code block or in a newly added encoding pass. The picture decoding apparatus and method comprise analyzing the input encoded codestream, extracting the inspection symbol from the portion of the preset code block or in the newly added encoding pass, applying error correction and decoding to data of a header and/or a packet or packets of one or more preset layers, using the inspection symbol, and decoding the encoded codestream following the error correction and decoding.

In generating an encoded codestream, in accordance with e.g. the JPEG-2000 system, by the above-described picture encoding apparatus and method, the error correction encoding is applied to data of a header and/or a packet or packets of a predetermined one or more layer, and the resulting inspection symbols are collected together and embedded in a predetermined lower layer, COM marker, in a portion of a predetermined code block or in a newly added encoding pass. In the picture decoding apparatus and method, the embedded inspection symbols are extracted and used to effect error correction and decoding of the data of the header and/or the packet or packets of a predetermined one or more layer.

In a further aspect, the present invention provides an error correction encoding apparatus and method comprising being supplied with an encoded codestream, generated on arithmetic coding of an input picture, splitting the supplied encoded codestream into a plurality of layers, generating a plurality of packets from one layer to another, applying error correction encoding to data of a header and/or a packet or packets of a predetermined one or more layers, and embedding inspection symbols, generated by the error correction encoding, in the packet of a predetermined lower layer.

In a further aspect, the present invention provides an error correction decoding apparatus and method comprising being supplied with an encoded codestream, generated on arithmetic coding of an input picture, splitting the supplied encoded codestream into a plurality of layers, generating a plurality of packets from one layer to another, applying error correction encoding to data of a header and/or a packet or packets of a predetermined one or more layers, and embedding an inspection symbol, generated by the error correction encoding means, in a packet of a predetermined lower layer, applying error correction to data of a header and/or a packet or packets of a predetermined one or more layers, and embedding inspection symbols, generated by the error correction encoding, in the packet of a predetermined lower layer. The input encoded codestream is analyzed, the inspection symbols are extracted from the packet of the lower layer and, using these inspection symbols, the error correction and decoding is applied to the data of the header and/or a packet or packets of predetermined one or more layers.

In a further aspect, the present invention provides an error correction encoding apparatus and method comprising being supplied with an encoded codestream, generated on arithmetic coding of an input picture, splitting the supplied encoded codestream into a plurality of layers, generating a plurality of packets from one layer to another, applying error correction encoding to data of a header and/or a packet or packets of a predetermined one or more layers, and embedding means for embedding an inspection symbol generated by the error correction encoding means in a COM marker of a main header or a tile part header.

In a further aspect, the present invention provides an error correction decoding apparatus and method in which an input encoded codestream is supplied and the supplied encoded codestream is decoded to restore an input picture. The encoded codestream is such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding inspection symbols generated on this error correction coding in the packets of a COM marker of a main header or a tile part header. The picture decoding apparatus and method comprise analyzing the input encoded codestream, extracting the inspection symbol from the COM marker, and applying error correction and decoding to data of a header and/or a packet or packets of one or more preset layers, using the inspection symbols.

In a further aspect, the present invention provides an error correction encoding apparatus and method comprising being supplied with an encoded codestream obtained on applying filtering to an input picture in a picture encoding apparatus to generate a plurality of sub-bands, splitting the generated sub-bands to generate a plurality of code blocks, each being of a predetermined size, generating a plurality of bitplanes from the most significant bit to the least significant bit, from one of the code blocks to another, performing bit modeling from one bitplane to another to generate a plurality of encoding passes, and on performing arithmetic coding in the generated encoding passes to generate an encoded codestream, splitting the encoded bitstream into a plurality of layers, generating a plurality of packets from one layer to another, applying error correction encoding to data of a header and/or a packet or packets of a predetermined one: or more layers, and embedding an inspection symbol generated by the error correction encoding means in a portion of a predetermined code block or in a newly added encoding pass.

In a further aspect, the present invention provides an error correction apparatus and method in which an input encoded codestream is supplied and the supplied encoded codestream is decoded to restore an input picture, with the encoded codestream being such a one obtained on filtering the input picture in a picture encoding apparatus to generate a plurality of sub-bands, splitting the generated sub-bands to generate a plurality of code blocks each being of a predetermined size, generating a plurality of bitplanes from the most significant bit to the least significant bit, from one code block to another; performing bit modeling from one bitplane to another to generate a plurality of encoding passes, performing arithmetic coding in the generated encoding passes to generate an encoded codestream, splitting the encoded bitstream into a plurality of layers, generating a plurality of packets from one layer to another, applying error correction and encoding to data of a header and/or the packet of preset one or more layers to generate an inspection symbol, and on embedding the generated inspection symbol in a portion of the preset code block or in a newly added encoding pass. The picture decoding apparatus and method comprise analyzing the input encoded codestream, extracting the inspection symbol from the portion of the preset code block or in the newly added encoding pass, and applying error correction and decoding to data of a header and/or a packet or packets of one or more preset layers, using the inspection symbol.

In the above-described apparatus and method for error correction encoding apparatus and method, an encoded codestream, generated in accordance with e.g. the JPEG-2000 system, is input, error correction encoding is applied to data of a header and/or a packet(s) of a predetermined one or more layers, the resulting inspection symbols are collected together and embedded in a predetermined lower layer, a COM marker, in a portion of a predetermined code block or in a newly added encoding pass. In the error correction decoding apparatus and method, the embedded inspection symbols are extracted and, using these inspection symbols, the data of the header and/or a packet(s) of a predetermined one or more layers are corrected for errors and decoded.

With the picture encoding apparatus and method and the picture decoding apparatus and method, according to the present invention, described above, in case an encoded codestream is generated in the picture encoding apparatus in accordance with e.g. the JPEG-2000 system, error correction and encoding is applied to the data of the header and/or the packet(s) of predetermined one or more layers, to produce inspection symbols, these inspection symbols are collected together and embedded in a portion of a predetermined lower layer, a COM marker, a portion of a predetermined code block or in a newly added encoding pass. In the picture decoding apparatus, the embedded inspection symbols are extracted and, using these inspection symbols, error correction and decoding is applied to the data of the header and/or the packet(s) of predetermined one or more layers. By so doing, error correction encoding can be applied readily efficiently in encoding, while error correction can be performed in decoding. Moreover, by changing e.g. the number of the layers as the subject entity of the error correction and encoding, the error correction capability can be changed depending on the error rate of the communication channel on which to transmit the encoded codestream.

With the error correction encoding apparatus and method and the error correction decoding apparatus and method according to the present invention, an encoded codestream, generated in accordance with e.g. the JPEG-2000 system, is supplied to the error correction encoding apparatus, error correction encoding is applied to data of the header and/or the packet(s) of predetermined one or more layers, to generate inspection symbols. These inspection symbols are collected together and embedded in a portion of a predetermined lower layer, a COM marker, a portion of a predetermined code block or in a newly added encoding pass. In the error correction decoding apparatus, the embedded inspection symbols are extracted and, using these inspection symbols, error correction decoding is applied to the data of the header and/or the packet(s) of predetermined one or more layers. By so doing, error correction decoding may be applied extremely readily efficiently to the encoded codestream to effect error correction prior to decoding. Moreover, by changing e.g. the number of the layers as the subject entity of the error correction and encoding, the error correction capability can be changed depending on the error rate of the communication channel on which to transmit the encoded codestream.

### BRIEF DESCRIPTION OF THE DRAWINGS

FIG. 1 illustrates a schematic structure of a picture encoding apparatus of a first embodiment of the present invention.

FIG. 2 illustrates sub-bands obtained on wavelet transform up to the second level.

FIG. 3 illustrates the relationship between a code block and a sub-band.

FIGS. 4A to 4C illustrate bitplanes, where FIG. 4A shows 16 quantization coefficients, FIG. 4B shows bitplanes of absolute values of the coefficients and FIG. 4C shows a sign bitplane.

FIG. 5 illustrates the processing sequence of encoding passes in a code block.

FIG. 6 illustrates the coefficient scanning sequence in a code block.

FIG. 7 illustrates the structure of layers 0 to 2 and a packet structure.

FIG. 8 illustrates a packet header and a packet body.

FIG. 9 illustrates a specified example of embedding inspection symbols in the lowermost layer.

FIG. 10 illustrates a schematic structure of a picture decoding apparatus of the first embodiment of the present invention.

FIG. 11 illustrates a specified example in which the lowermost layer is exempted from the encoded codestream after error correction decoding employing the inspection symbol embedded in the lowermost layer.

FIG. 12 illustrates a specified example in which data of the lowermost layer are all set to 0 after error correction decoding employing the inspection symbol embedded in the lowermost layer.

FIG. 13 illustrates a schematic structure of a picture encoding apparatus of a second embodiment of the present invention.

FIG. 14 illustrates a schematic structure of a picture decoding apparatus of the second embodiment of the present invention.

FIG. 15 illustrates a specified example in which an inspection symbol is embedded in an added encoding pass in a picture encoding apparatus.

FIG. 16 illustrates a specified example in which the inspection symbol is extracted from the added encoding pass.

### DESCRIPTION OF THE PREFERRED EMBODIMENTS

Referring to the drawings, preferred embodiments of the present invention will be explained in detail.

(1) First Embodiment

(1-1)

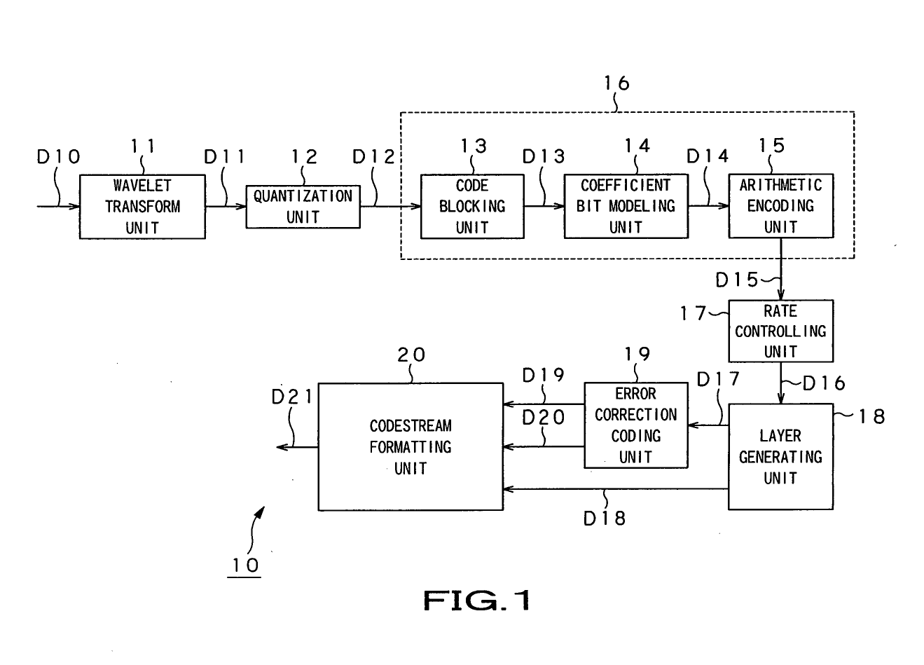

FIG. 1 shows a schematic structure of a picture encoding apparatus of a first embodiment of the present invention. Referring to FIG. 1, a picture encoding apparatus 10 is formed by a wavelet transform unit 11, a quantization unit 12, a code blocking unit 13, a coefficient bit modeling unit 14, an arithmetic encoding unit 15, a rate controlling unit 17, a layer generating unit 18, an error correction coding unit 19 and a codestream formatting unit 20. The code blocking unit 13, coefficient bit modeling unit 14 and the arithmetic encoding unit 15 go to make up an EBCOT (embedded coding with optimized truncation) unit 16.

The wavelet transform unit 11 is usually implemented as a filter bank formed by a low pass filter and a high pass filter. Meanwhile, a digital filter usually has an impulse response of plural tap lengths (filter coefficients) and hence an amount of input pictures sufficient to permit filtering needs to be buffered at the outset. This, however, is not shown in FIG. 1 for simplicity.

The wavelet transform unit 11 is supplied with an amount of picture signals D1, as a necessary minimum amount to permit filtering, and applies filtering by way of wavelet transform to generate wavelet transform coefficients D11.

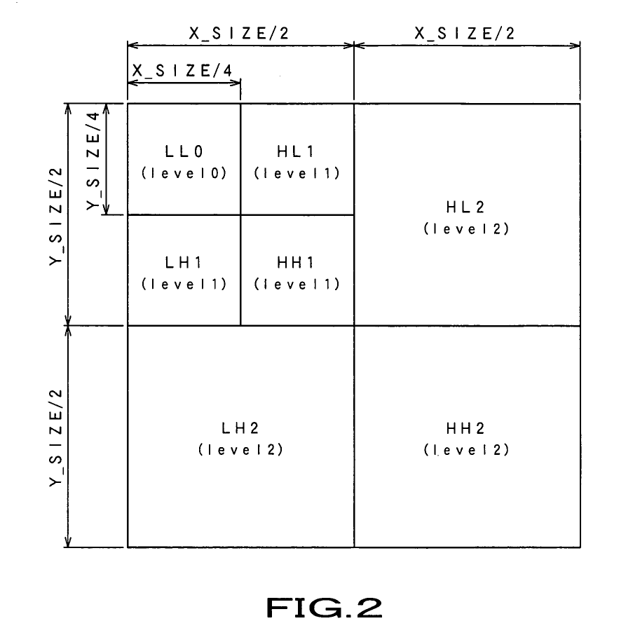

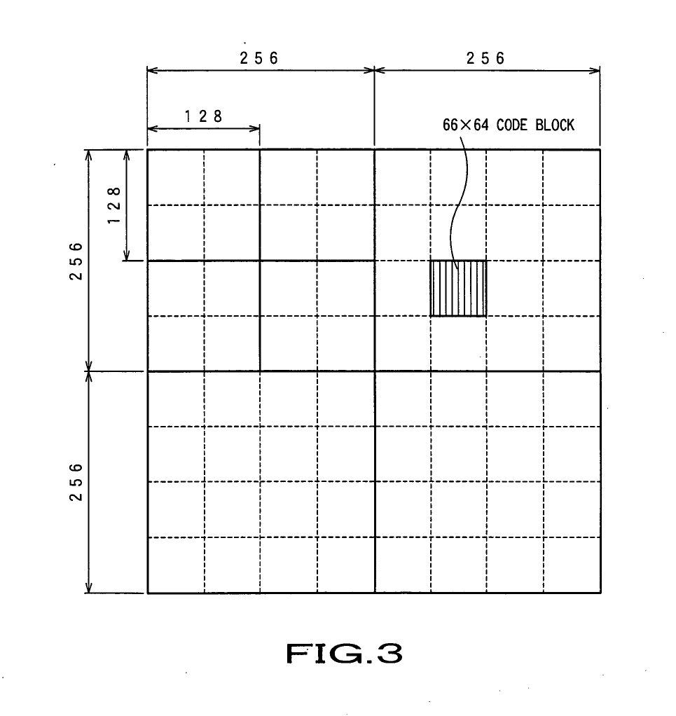

In this wavelet transform, low frequency components are usually repeatedly transformed, as shown in FIG. 2, because the major portion of the energy of the picture is concentrated in the low frequency components. The number of levels in the wavelet transform of FIG. 2 is two, as a result of which seven sub-bands are generated. That is, the first filtering processing divides the size along the horizontal direction X_size and that along the vertical direction Y size by half so that four sub-bands of LL1, LH2, HL2 and HH2 are generated. The second filtering processing further sub-divides LL1 so that four sub-bands LL10, LH1, HL1 and HH1 are generated. In FIG. 2, L and H denote the low frequency range and the high frequency range, respectively, and the suffix numbers after L and H denote the resolution level. For example, LH1 denotes a sub-band, with the resolution level=1, which is low in the frequency range in the horizontal direction and which is high in the frequency range in the vertical direction. The quantization unit 12 applies irreversible compression to the wavelet transform coefficients D11 supplied from the wavelet transform unit 11. As quantization means, scalar quantization of dividing the wavelet transform coefficients D11 with a quantization step size may be used.

The code blocking unit 13 divides the sub-band based quantization coefficients D12, generated in the quantization unit 12, into code blocks, as encoding units provided for in JPEG-2000. That is, code blocks of, for example, 64×64 in size, are generated in the totality of the sub-bands, obtained on division. Meanwhile, according to JPEG-2000 prescriptions, the code block size is represented in both the horizontal direction and the vertical direction by powers of 2. Usually, the code block size of 32×32 or 64×64 is preferentially used. The code blocking unit 13 sends the code block based quantization coefficients D13 to >the bit modeling unit 14.

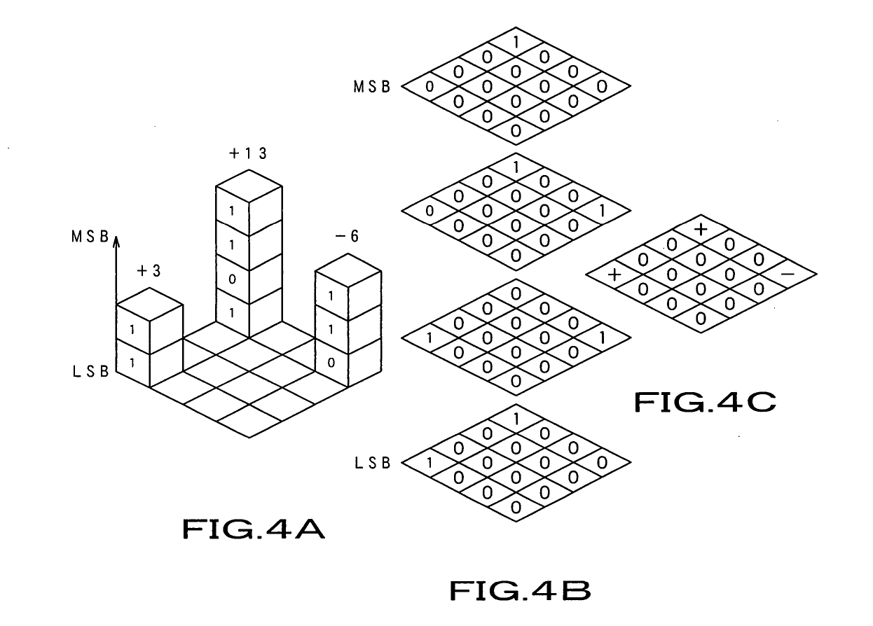

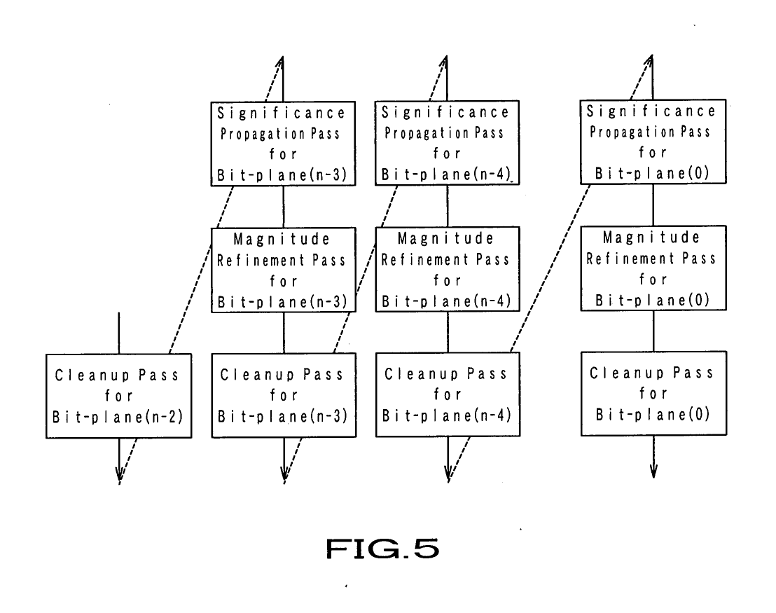

The coefficient bit modeling unit 14 performs coefficient bit modeling on the code block based quantization coefficients D13 in the following manner on the bitplane basis. The concept of the bitplane is now explained by referring to FIG. 4.

In FIG. 4A quantization coefficients comprising 4 longitudinal by 4 transverse coefficients, totaling at 16 coefficients, are presupposed. Of these 16 coefficients, the coefficient having the maximum absolute value is 13, which is 1101 in binary representation. Consequently, the absolute values of the coefficients are constituted by four bitplanes shown in FIG. 4B. Meanwhile, the totality of the elements of the bitplanes assume the values of 0 or 1. On the other hand, the sign of the quantization coefficient is minus only for −6, with the other quantization coefficients being 0 or of positive values. Thus, the bitplane for the sign is as shown in FIG. 4C.

In the present embodiment, the entropy encoding, termed EBCOT, provided for in particular in JPEG-2000 standard, is used. The processing unit of EBCOT is the aforementioned code block. Meanwhile, the EBCOT is explained in great detail in for example a reference material entitled: ‘ISO/IEC 15444-1, Information technology-JPEG 2000, Part 1: Core coding system’.

Each code block is encoded independently, from the most significant but (MSB) towards the least significant bit (LSB), from one bitplane to another. The quantization coefficients are represented by n-bit signed binary number, with respective bits from the LSB to the MSB being indicated by bit 0 to bit (n−2). The remaining one bit is a sign bit. The code blocks are sequentially encoded, beginning from the MSB side bitplane, by the following three encoding passes (a) to (c):

(a) a significance propagation pass;

(b) a magnitude refinement pass; and

(c) a cleanup pass.

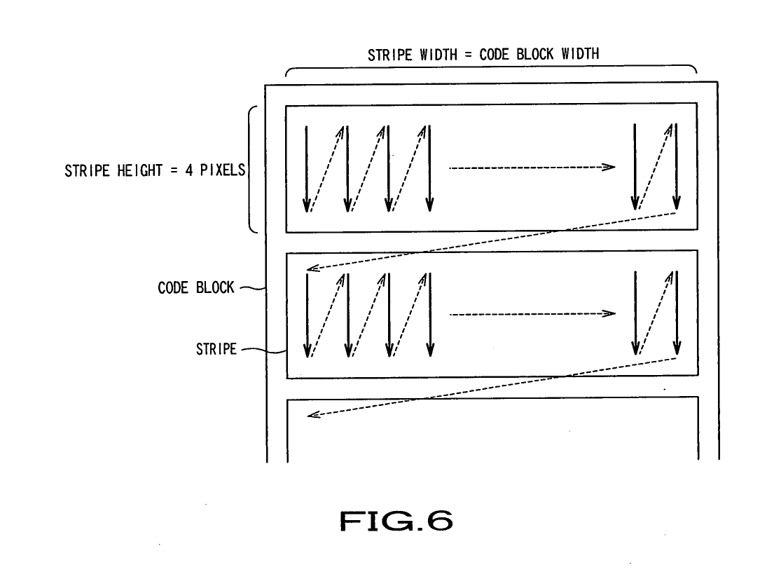

FIG. 5 shows the sequence in which the three encoding passes are used. Referring to FIG. 5, the bitplane (n−2) (MSB) is encoded, first of all, by a cleanup pass (sometimes referred to below as CU pass). The processing proceeds sequentially towards the LSB side, so that the respective bitplanes are encoded, using the significance propagation pass (sometimes referred to below as SP pass), the magnitude refinement pass (sometimes referred to below as MR pass) and the cleanup pass, in this order.

In actuality, in which number bitplane, as counted from the MSB side, “1” appears for the first time, is written in a header, while the bitplanes made up by zero coefficients only (zero bitplane) are not encoded. The bitplanes are encoded, repeatedly using the three sorts of the encoding passes. The encoding may be discontinued at an optional encoding pass of an optional bitplane, in order to take trade-off between the code volume and the picture quality, by way of performing rate control.

Referring to FIG. 6, the scanning of coefficients is explained. Each code block is divided into stripes every four coefficient bits in the height-wise direction. The stripe width is equal to the width of the code block. The scanning sequence means a sequence in which the totality of coefficient bits in a given code block are scanned. Specifically, the coefficient bits are scanned from an upper stripe towards a lower stripe in a given code block, from a left column towards a right column in a given stripe and from above to below in each column. It is noted that, in each encoding pass, the totality of the coefficients in a code block are processed in this scanning order.

The aforementioned three encoding passes are hereinafter explained.

(a) Significant Propagation Pass

In an SP pass for encoding a given bitplane, non-significant coefficient bits in which at least one coefficient in the vicinity of 8 is significant are encoded by arithmetic coding. If the value of the encoded bitplane is 1, the sign (plus or minus sign) of the code is then encoded by arithmetic coding.

The ‘significance’ means the state an encoder has for each coefficient. The initial value of the significance is [0] indicating being non-significant, and is changed to [1], indicating being significant, when [1] is encoded with the coefficient. The value then continues to be [1] at all times. Consequently, the ‘significance’ may be said to be a flag indicating whether or not the information of an effective digit has already been encoded.

(b) Magnitude Refinement Pass

In the MR pass, encoding a bitplane, the value of a bitplane of a ‘significant’ coefficient, not encoded in the SP pass, encoding a bitplane, is arithmetically encoded. (c) Clean up pass

In the Cu pass, encoding a bitplane, the value of a bitplane of a ‘non-significant’ coefficient, not encoded in the SP pass, encoding the bitplane, is arithmetically encoded. If the value of the encoded coefficient bit is 1, the sign (plus or minus sign) is then arithmetically encoded.

In the arithmetic coding of the above-described three encoding passes, the context of the coefficients is selected as ZC (zero coding), RLC (run-length coding), SC (sign coding) and MR (magnitude refinement) are selectively used case-by-case. The context selected is encoded by arithmetic coding termed the MQ encoding. This MQ encoding is a learning type bi-level arithmetic coding provided for in JPEG2. The MQ encoding is described in for example a reference material [ISO/IEC FDIS 14492, ‘Lossy/Lossless Coding of Bilevel Images’, March 2000]. The JPEG-2000 provides for a sum total of 19 sorts of contexts in the totality of the encoding passes.

The bit modeling unit 16 resolves the code block based quantization coefficients D13 into bitplanes, while resolving each bitplane in three encoding passes to generate quantization coefficients D14 from one encoding pass to another. The arithmetic coding unit 15 applies arithmetic coding to these encoding pass based quantization coefficients D14.

The rate controlling unit 17 performs code volume control, as it counts the code volume of the arithmetic code D15, supplied from the arithmetic coding unit 15, so as to approach to the target bitrate or the target compression ratio. Specifically, the rate controlling unit 17 manages code volume control by truncating at least a portion of the code block based encoding pass.

The layer generating unit 18 splits the rate controlled code block based encoded codestream D16, supplied from the rate controlling unit 17, into a predetermined number of layers.

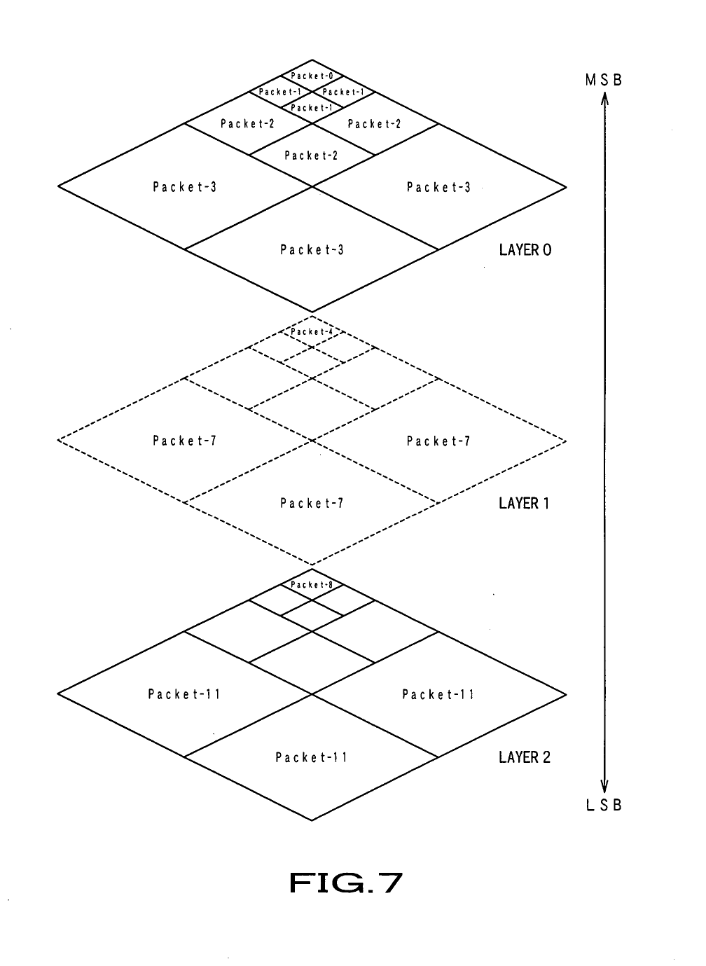

Referring to FIG. 7, the concept of the layer is explained. FIG. 7 shows an instance where there are provided three layers of 0, 1 and 2, with each layer being composed of four packets. That is, the lowermost range (LL component), the next high resolution level, the still next high resolution level and the highest resolution level of a layer 0 (most significant layer or MSB) are a packet −0, a packet −1, a packet −2, a packet −3, respectively. For the next and the following layers, packets may be defined in an identified manner, such that, in the layer 2, packets are generated up to the packet −11.

Although the splitting level of the wavelet transform is three in FIG. 7, and hence the four packets are formed in each layer, the number of packets in each layer may, of course, be changed by changing the number of the splitting levels.

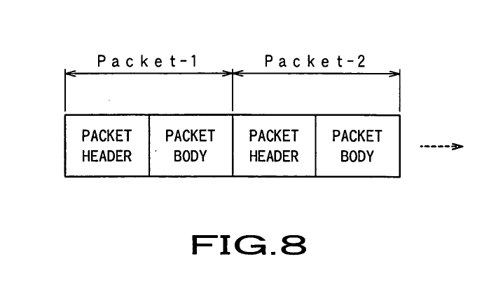

Referring to FIG. 8, each packet is formed by a packet header and a packet body. In the packet header, there are stated variable sorts of the information of plural code blocks present in a packet. These stated contents are all defined in the JPEG-2000 standard. On the other hand, actual encoded codestreams of these code blocks are recorded in the packet body.

Reverting to FIG. 1, the layer generating unit 18 sends, from among encoded codestream D16 of the multi-layered structure, data D17 of a packet to be processed with error correction encoding, such as a data of header, data of a packet or-packets of the layer subjacent to the uppermost layer or a packet of the layer subjacent to the layer next to the second upper layer, to the error correction coding unit 19, while sending data D18 of the packet of the other layer to a codestream formatting unit 20.

The error correction coding unit 19 applies error correction coding to the data D17, to be processed with error correction coding, using e.g. the Reed-Solomon code (see I. S. Reed and G. Solomon, “Polynominal codes over certain finite fields”, J. Society of Industrial and Applied Mathematics, vol.8, pp.300 to 304, June 1960). If RS (15, 13) is used as the RS code, one symbol error, with 1 symbol being formed by four bits, may be corrected. That is, in the present case, burst errors up to a maximum of four bits may be corrected. After the error correction coding, two symbols, namely an information symbol and an inspection symbol, are usually generated. Of these, the information symbol is known to be completely coincident with the original information prior to the error correction coding. The error correction coding unit 19 sends the inspection symbol D19 and the information symbol D20, following the error correction coding, to the codestream formatting unit 20.

The codestream formatting unit 20 embeds the inspection symbol D19 in a predetermined lower layer, for example, in the lowermost layer, in an encoded codestream. That is, the codestream formatting unit substitutes the inspection symbol D19 for the data of the lowermost layer. The codestream formatting unit 20, integrates the inspection symbol D19, embedded in e.g. the lowermost layer, the information symbol D20 and the data D18 of the packet of the layer which is not the subject entity of the error correction and coding, to generate and output a new encoded codestream D21. Although the destination of the embedding of the inspection symbol D19 is not limited to the lowermost layer, this layer affects the picture quality only to a lesser extent and hence is desirable as the destination of the embedding.

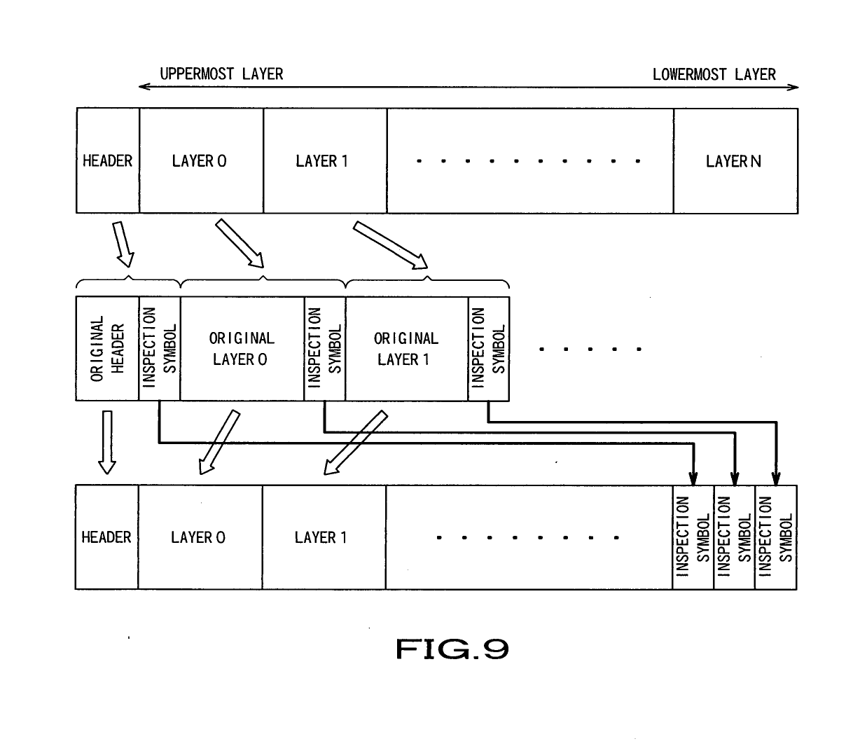

The above-described processing is specifically shown in FIG. 9. Meanwhile, this FIG. 9 illustrates an instance in which error correction encoding has been applied to data of the header, and to data of the packets of the uppermost layer (layer 0) and the next upper layer (layer 1). In this case, an original information symbol D20 and an inspection symbol D19 are generated. Of these, the inspection symbol D19 is embedded in a layer N as the lowermost layer.

It is noted that, if the data volume of the inspection symbol D19 is lesser than the data volume of the inherent lowermost layer, the inspection symbol D19 can be completely embedded in the lowermost layer. However, if the data volume of the inspection symbol D19 is larger than that of the inherent lowermost layer, data overflow occurs. In such case, the inspection symbol D19 may be embedded not in the lowermost layer only, but across the lowermost layer and a plural upper layers.

Thus, the picture encoding apparatus 10 of the present embodiment applies error correction encoding to predetermined data portions in the encoded codestream, such as data of the header, and to the data of the packets of the uppermost layer and the layer subjacent to the uppermost layer, and collectively embeds the produced inspection symbols in a predetermined lower layer, such as the lowermost layer.

In the above explanation, the inspection symbol following the error correction encoding is embedded in a predetermined lower layer. This, however, is merely illustrative, such that the inspection symbol may be appended to the trailing side of the original data of a predetermined lower layer. However, since the total data length of the lower layer becomes excessively long, in this case, such that it becomes necessary to update the data length of data stated in the packet header of each packet of the lower layer.

In the foregoing explanation, error correction coding is applied to the header and to data of the header, uppermost layer and the subjacent layer. However, the subject entity of the error correction encoding may, of course, be selected arbitrarily. For example, such a setting may be made in which, if the error rate of the communication channel, over which the encoded codestream D21 is sent, is high, the number of layers, as the subject entity of the error correction encoding, is increased, and the header information is included into the subject entity of the error correction encoding and in which, if the error rate is low, the number of layers, as the subject entity of the error correction coding, is diminished.

(1-2)

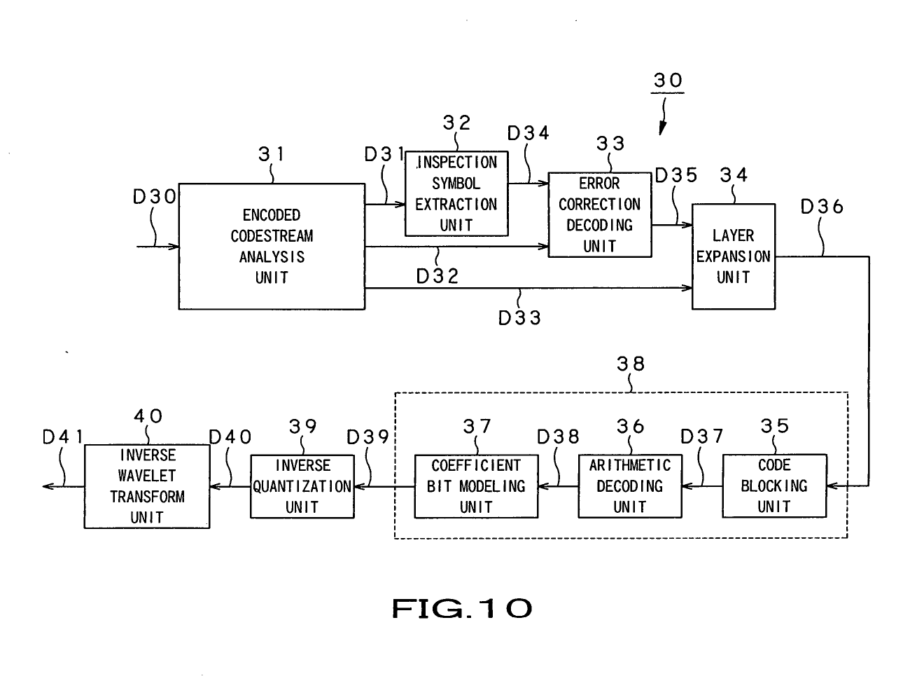

The schematic structure of a picture decoding apparatus, according to a first embodiment of the present invention, is schematically shown in FIG. 10. Referring to FIG. 10, a picture decoding apparatus 30 of the present first embodiment is formed by an encoded codestream analysis unit 31, an inspection symbol extraction unit 32, an error correction decoding unit 33, a layer expansion unit 34, a code blocking unit 35, an arithmetic decoding unit 36, a coefficient bit modeling unit 37, an inverse quantization unit 39 and an inverse wavelet transform unit 40. The code blocking unit 35, arithmetic decoding unit 36 and the coefficient bit modeling unit 37 go to make up an EBCOT decoding unit 38.

The encoded codestream analysis unit 31, supplied with an encoded codestream D30, analyzes the number of layers or packet data in each layer, and sends data D31 of a packet or packets of a predetermined lower layer, having embedded the inspection symbol, to the inspection symbol extraction unit 32. The encoded codestream analysis unit 31 also sends the error corrected and encoded information symbol D32 of e.g. the header, uppermost layer and the next upper layer subjacent to the uppermost layer, to the error correction decoding unit 33, while sending the data D33 of the packets of the other layers to the layer expansion unit 34.

The inspection symbol extraction unit 32 extracts the inspection symbol D34, from the data D31 of a packet or packets of the predetermined lower layer to send the so extracted inspection symbol to the error correction decoding unit 33. Using the inspection symbol D34, the error correction decoding unit 33 applies error correction decoding to the information symbol D32. By so doing, burst errors up to a maximum of 4 bits in the codes subjected to RS (15, 13) may be corrected if such errors have been produced e.g. in the header or in the uppermost layer. The error correction decoding unit 33 sends the error corrected decoded data D35 of the header information and a packet or packets of the uppermost layer and the layer subjacent to the uppermost layer to the layer expansion unit 34.

The layer expansion unit 34 is supplied with the data D33 of the packets of the layer, which is not the subject entity of error correction decoding, and with data D35 of the error corrected and decoded packets, and causes the data to be expanded in the encoded codestream D36 of the multi-layer structure. The layer expansion unit 34 discards the predetermined lower layer, having embedded the inspection symbol, to exclude the layer from the encoded codestream. The reason is that decoding the lowermost layer different than the inherent lowermost layer of a picture in the course of the decoding produces the noise in the overall picture. For reducing such effect on the picture, it is possible for the layer expansion unit 34 to set data of the lowermost layer, having embedded the inspection symbol, to zero in their entirety to get the resulting lowermost layer included in the encoded codestream.

The code blocking unit 35 is supplied with the encoded codestream of the multi-layer structure D36, collects the arithmetic codes on the code block basis, and sends the code block based arithmetic codes D37 to the arithmetic decoding unit 36. As from this time, the decoding process in the EBCOT decoding unit 38 is carried out on the code block basis.

The arithmetic decoding unit 36 applies arithmetic decoding to code block based arithmetic codes D37, supplied from the code blocking unit 35, to generate quantization coefficients D38. The coefficient bit modeling unit 37 restores quantization coefficients D39 from the quantization coefficients D38.

The inverse quantization unit 39 inverse-quantizes the quantization coefficients D39, supplied from the coefficient bit modeling unit 37, for conversion to wavelet transform coefficients D40. The inverse wavelet transform unit 40 inverse-transforms the wavelet transform coefficients D40 to output a decoded picture D41.

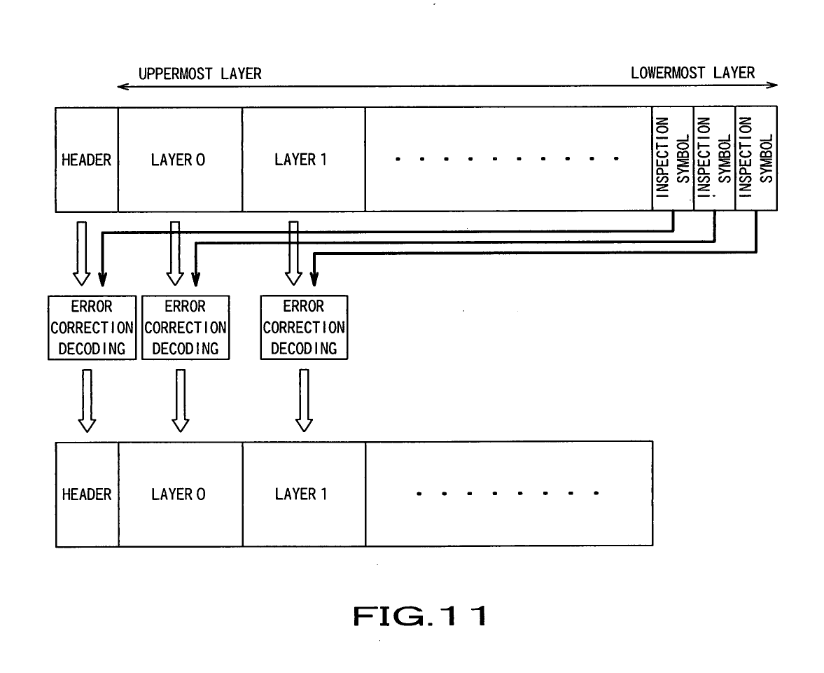

The above processing is shown specifically in FIG. 11. This FIG. 11 illustrates an instance where the inspection symbols of the header, uppermost layer (layer 0) and the layer subjacent to the uppermost layer (layer 1) have been embedded in the lowermost layer. In this case, an error corrected header is generated, as a result of the error correction decoding which is carried out using the header information symbol and the header inspection symbol. In similar manner, an error corrected layer 0 is generated, as a result of the error correction decoding which is carried out using the layer 0 information symbol and the layer 0 inspection symbol, whilst an error corrected layer 1 is generated, as a result of the error correction decoding which is carried out using the layer 1 information symbol and the layer 1 inspection symbol.

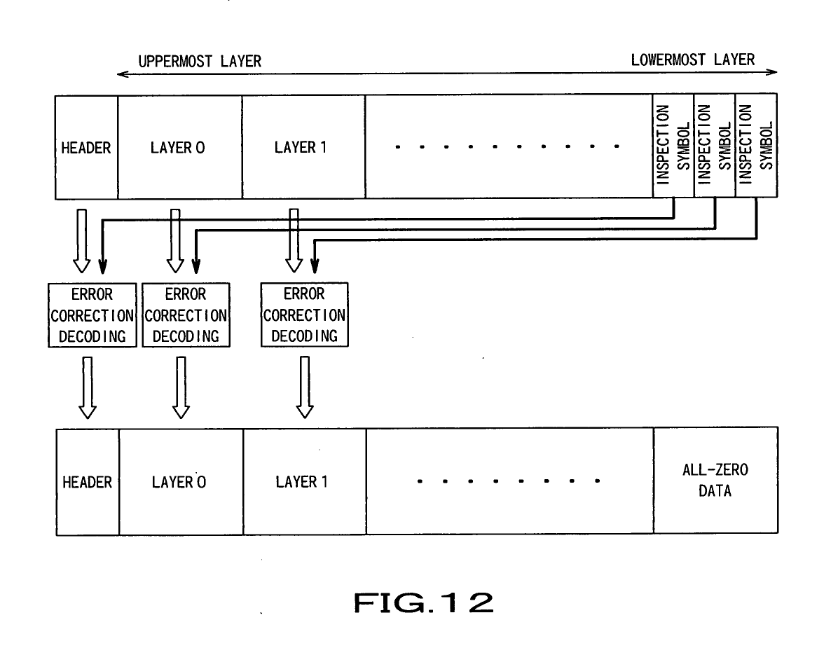

Meanwhile, if the inspection symbol is embedded in the lowermost layer, as shown in FIG. 11; there is no data other than the inspection symbol in the data of the lowermost layer. It is therefore desirable that, as shown in FIG. 11, the layer expansion unit 34 discards the lowermost layer and exclude it from the encoded codestream. It is also possible to set the data of the lowermost layer all to zero and to get the resulting data included in the encoded codestream as shown in FIG. 12.

Thus, with the above-described first embodiment of the picture encoding apparatus 10 and the picture decoding apparatus 30, the error correction encoding can be efficiently applied in the course of picture compression according to the JPEG-2000 system.

Moreover, since the degree of intensity of the error correction encoding can be controlled by the number of layers or code blocks, as the subject entity of error correction encoding, more flexible accommodation becomes possible in dependence upon the error rate on the communication route on which to transmit the encoded codestream.

There is also an advantage that, in case an inspection symbol is substituted for the data of the packets of the predetermined lower layer, the overall code volume of the encoded codestream is not increased and hence the compression ratio is not concomitantly lowered.

(2) Second Embodiment

(2-1)

In the above-described first embodiment, error correction encoding is applied as the encoded codestream is being generated in the inside of the picture encoding apparatus 10. The present second embodiment is featured by applying error correction encoding to the encoded codestream generated in the picture encoding apparatus.

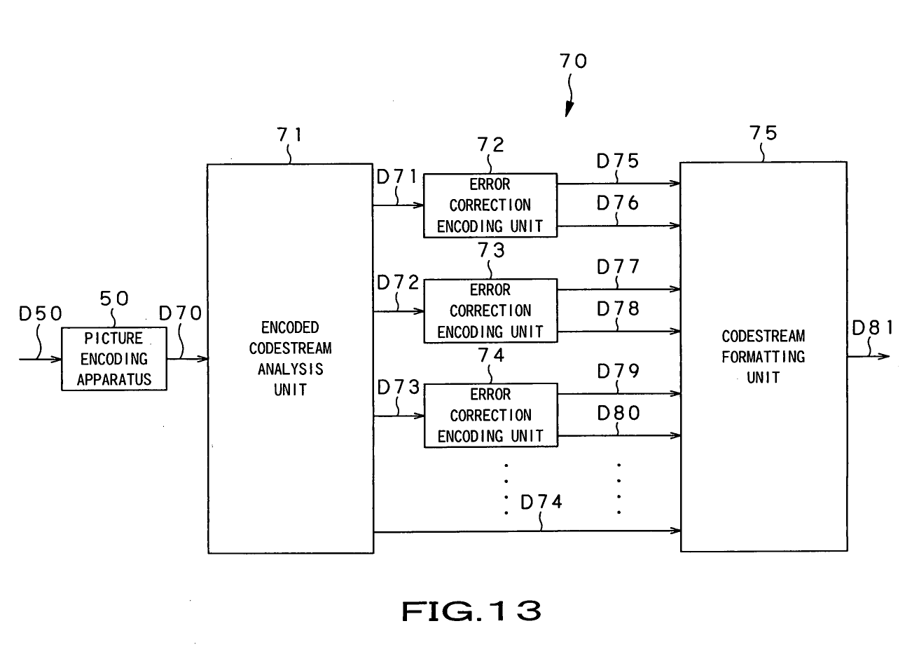

FIG. 13 shows a schematic structure of an error correction encoding apparatus of the present embodiment. In this FIG. 13, a picture encoding apparatus 50 for generating an encoded codestream is also shown. Referring to FIG. 13, an error correction encoding apparatus 70 of the present embodiment is formed by an encoded codestream analysis unit 71, error correction encoding units 72 to 74, and a codestream formatting unit 75.

The picture encoding apparatus 50 encodes the input picture D50, in accordance with the algorithm conforming to JPEG-2000, and sends the generated encoded codestream D70 to the encoded codestream analysis unit 71 of the error correction encoding apparatus 70.

The encoded codestream analysis unit 71 analyzes the contents of the encoded codestream D70 and sends data D71 of a header, such as a main header, data D72 of the packets of the lowermost layer and data D73 of the packet or packets of the layer subjacent to the uppermost layer, to the error correction encoding units 72, 73 and 74, respectively, while sending data D74 of the packets of the other layers to the codestream formatting unit 75.

The error correction encoding unit 72 applies-error correction encoding to the header data D71, using e.g. the Reed-Solomon (RS) code, to send an inspection symbol D75 and an information symbol D76 following the error correction and encoding to the codestream formatting unit 75. In similar manner, the error correction encoding units 73, 74 apply error correction encoding to data D72 of the uppermost layer and to data D73 of the packets of the layer subjacent to the uppermost layer, and send inspection symbols D77, D79 and information symbols D78, D80, following the error correction, to the codestream formatting unit 75. The codestream formatting unit 75 embeds the inspection symbols D75, D77 and D79 in a predetermined lower layer in an encoded codestream, for example, in the lowermost layer.

The codestream formatting unit 75 integrates the inspection symbol D75, D77 and D79, embedded in e.g. the lowermost layer, the information symbols D76, D78 and D80 and the data D74 of the packet of the layer, which is not the subject entity of the error correction and coding, to generate and output a new encoded codestream D81.

In this manner, the present embodiment of the error correction encoding apparatus 70 analyzes the encoded codestream D70, generated by the picture encoding apparatus 50, applies error correction encoding to a predetermined data portion in the encoded codestream, such as header, uppermost layer and the layer subjacent to the uppermost layer, and collectively embeds the resulting inspection symbols in a predetermined lower layer.

In the above explanation, the error correction encoding unit is divided into three portions. In actuality, error correction encoding may be applied by the sole error correction encoding unit to the header, uppermost layer and the layer subjacent to the uppermost layer.

Moreover, in the above explanation, the inspection symbol following the error correction encoding is embedded in e.g. the lowermost layer. This, however, is merely illustrative, such that, for example, the inspection symbol may be appended to the rear side of the original data of the lowermost layer. However, since the total data length of the lowermost layer is increased in this case, it is necessary to update the data length stated in the packet headers of the packets forming the lowermost layer.

In the above explanation, the error correction encoding is applied to the header information, the uppermost layer and the layer subjacent to the uppermost layer. However, the subject entity of the error correction encoding can, of course, be set freely. For example, if the error rate of the communication route, on which to transmit the encoded codestream D81, is high, such a setting is possible in which the number of layers to be error corrected and encoded is increased and the header information is also included in the subject entity of the error correction and encoding, and in which, if conversely the error rate is low, the number of layers to be error corrected and encoded is decreased.

(2-2)

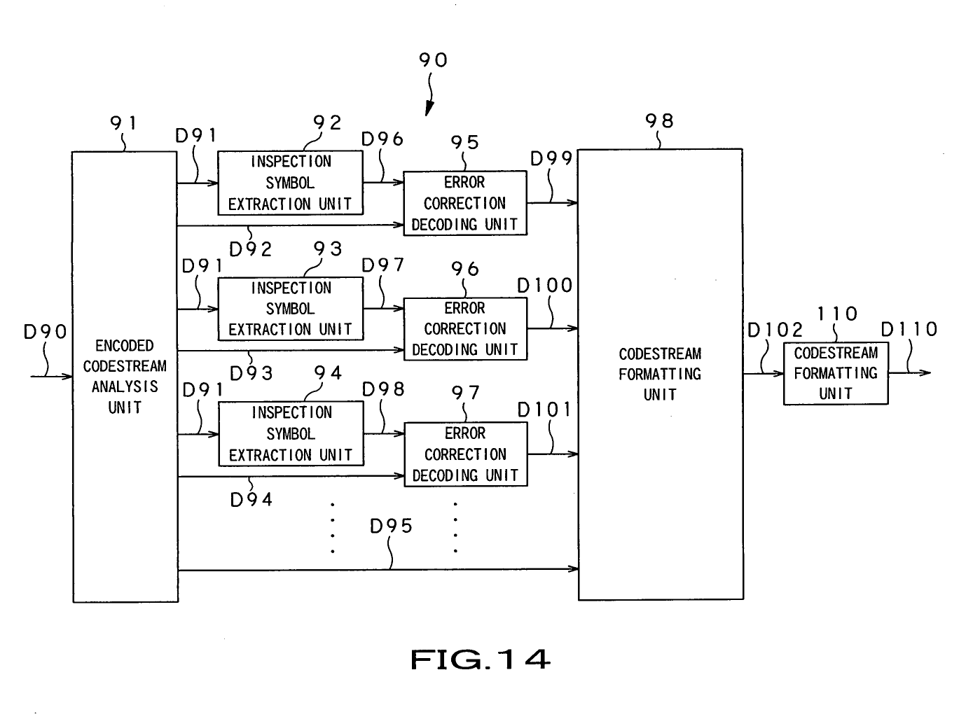

FIG. 14 shows the schematic structure of the error correction decoding apparatus in the second embodiment. FIG. 14 also shows a picture decoding apparatus 110 for decoding the error-corrected encoded codestream. Referring to FIG. 14, an error correction decoding apparatus 90 of the second embodiment is formed by an encoded codestream analysis unit 91, inspection symbol extraction units 92 to 94, error correction decoding units 95 to 97 and a codestream formatting unit 98. The encoded codestream analysis unit 91 analyzes an encoded codestream D90 of a multi-layer structure in accordance with the algorithm, conforming to the JPEG-2000, and supplies data D91 of the packets of the predetermined lower layer, having embedded the inspection symbol, to the inspection symbol extraction units 92 to 94, while supplying the information symbol D92 of the header, information symbol D93 of the uppermost layer and the symbol information D94 of the layer subjacent to the uppermost layer to the error correction decoding units 95, 96 and 97, respectively. The encoded codestream analysis unit 91 sends data D95 of the packets of the layer, not to be error corrected and decoded, to the codestream formatting unit 98.

The inspection symbol extraction unit 92 extracts an inspection symbol D96 of the header information from data D91 of the packets of a predetermined lower layer, such as the lowermost layer, and sends the inspection symbol D96 to the error correction decoding unit 95. In similar manner, an inspection symbol extraction unit 93 extracts the inspection symbol D97 of the uppermost layer from the data D91 of the packets of the predetermined lower layer to send the inspection symbol D97 to the error correction decoding unit 96. Moreover, the inspection symbol extraction unit 94 extracts the inspection symbol D98 of the layer subjacent to the uppermost layer from the data D91 of the packets of a predetermined lower layer to send the inspection symbol D98 to the error correction decoding unit 97.

The error correction decoding unit 95 performs error correction decoding, using the information symbol D92 and the inspection symbol D96 of the header to send the error corrected header data D99 to the codestream formatting unit 98. Similarly, the error correction decoding unit 95 performs error correction decoding using the information symbol D93 and the inspection symbol D97 of the uppermost layer to send the error corrected data D100 of the uppermost layer to the codestream formatting unit 98. Moreover, the error correction decoding unit 97 performs error correction decoding, using the information symbol D94 and the inspection symbol D98 of the layer subjacent to the uppermost layer to send the error corrected data D101 of the packets of the layer subjacent to the uppermost layer to the codestream formatting unit 98.

The codestream formatting unit 98 integrates the header data D99, data D100 of the packets of the uppermost layer, and data D101 of the packets of the layer subjacent to the uppermost layer, following the error correction and decoding, and data D95 of the packets of the layer not being error corrected decoded, to generate an ultimate encoded codestream D102, which ten is sent to the picture decoding apparatus 110.

The picture decoding apparatus 110 decodes the error corrected encoded codestream D102, in accordance with an algorithm conforming to the JPEG-2000, to output the decoded picture D110.

Thus, in the second embodiment of the error correction encoding apparatus 70 and the error correction decoding apparatus 90, error correction encoding can be efficiently applied to the encoded codestream conforming to the JPEG-2000. Moreover, the encoded codestream following the error correction and encoding also conforms to the standard of the JPEG-2000, and hence may be decoded using a general-purpose decoder.

Moreover, since the degree of intensity of the error correction encoding can be controlled by the number of layers as the subject entity of error correction encoding, or code blocks, more flexible accommodation becomes possible in dependence upon the error rate on the communication route on which to transmit the encoded codestream.

Additionally, when the inspection symbol is embedded in a predetermined lower layer, the code volume of the encoded codestream in its entirety is not increased, so that there may be derived an advantage that the compression ratio is not concomitantly lowered,

(3) Modification

The present invention is not limited to the embodiments described above and various changes, substitutions or equivalents may be envisaged without departing from the scope and the purport of the invention.

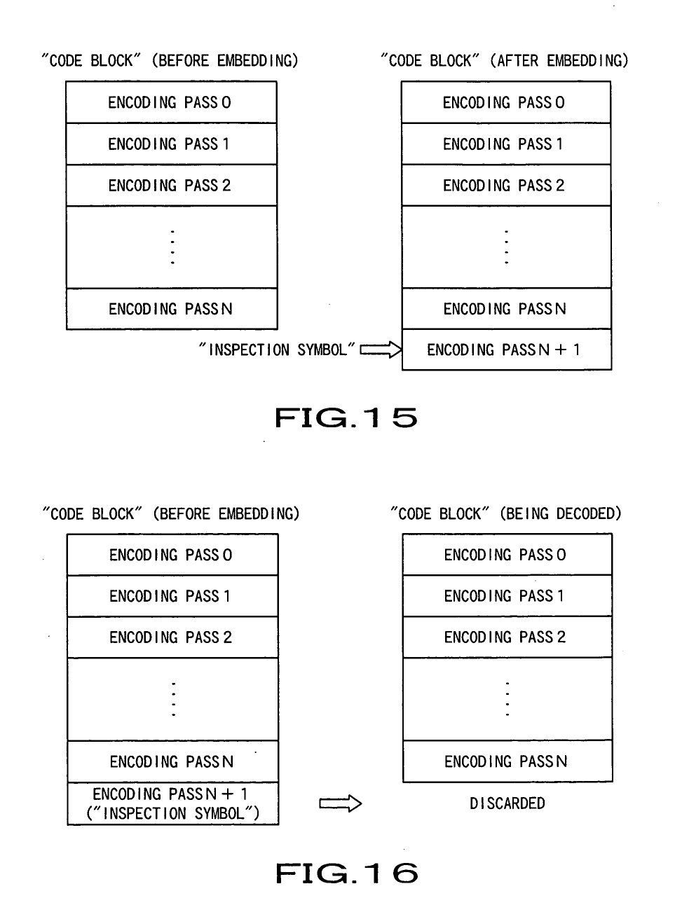

For example, in the above-described picture encoding apparatus 10 and the picture encoding apparatus 70, it is presupposed that the inspection symbol is embedded in a predetermined lower layer. This is merely illustrative such that it is also possible to increase the number of the encoding passes in the code block to and to embed the inspection symbol in the encoding pass. For example, if there are (N+1) coding passes of from the encoding pass 0 to the encoding pass N in a given code block, it is possible to add an encoding pass (N+1) newly and to embed the inspection symbol in this encoding pass (N+1), as shown in FIG. 15. Depending on the data volume of the inspection symbols, more encoding passes may also be added. However, since the number of the encoding passes in the code block is increased in this case, it is necessary to change the recorded number of the encoded passes in the packet header of the packets to which belongs the coding block. The inspection symbol may also be embedded in the pre-existing encoding pass, for example, in the encoding pass N of FIG. 15, instead of adding the new encoding pass.

In the picture decoding apparatus 30 and in the picture decoding apparatus 90, the inspection symbol is extracted from the encoding pass, having embedded the inspection symbol, to use the so extracted inspection symbol for error correction and decoding. After error correction, the encoding pass, having embedded the inspection symbol, as shown in FIG. 16, is desirably discarded and excluded from the encoded codestream. However, if deterioration of the picture quality is tolerated to a more or less extent, the encoding passes may be included in their entirety in the encoded codestream.

In the JPEG-2000 standard, a COM marker, which is a data area usable by a user, is provided in a main header and in a tile part header. Thus, the inspection symbol may be embedded in this COM marker in the picture encoding apparatus 10 and the picture encoding apparatus 70. In this case, the picture decoding apparatus 30 and in the picture decoding apparatus 90 extract the inspection symbol from the COM marker for use in the error correction and decoding.

What is claimed is:

1. A picture encoding apparatus comprising:
arithmetic encoding means for applying arithmetic encoding to an input picture to generate an encoded codestream;
splitting means for splitting said encoded codestream into a plurality of layers;
packet generating means for generating a plurality of packets from one layer to another;
error correction encoding means for applying error correction encoding to data of a header and/or a packet or packets of a predetermined one or more layers; and
embedding means for embedding an inspection symbol generated by said error correction encoding means in a packet or packets of a predetermined lower layer.

2. The picture encoding apparatus according to claim 1 wherein said predetermined one or more layers includes at least the uppermost layer.

3. The picture encoding apparatus according to claim 1 wherein said embedding means substitutes said inspection symbol for data of said packet or packets of said predetermined lower layer.

4. The picture encoding apparatus according to claim 3 wherein, if the data volume of said inspection symbol is larger than the data volume of the packets of said predetermined lower layer, said embedding means embeds said inspection symbol across the packets of a plurality of lower layers including said predetermined lower layer.

5. The picture encoding apparatus according to claim 1 wherein said embedding means appends said inspection symbol to data of a packet or packets of said predetermined lower layer.

6. The picture encoding apparatus according to claim 5 wherein said embedding means changes the data length stated in a packet header of a packet or packets of said predetermined lower layer.

7. The picture encoding apparatus according to claim 1 wherein said error correction encoding means sets the subject entity of the error correction encoding depending on the error rate of a communication channel on which said encoded codestream is transmitted.

8. A picture encoding apparatus comprising:
arithmetic encoding means for applying arithmetic encoding to an input picture to generate an encoded codestream;
splitting means for splitting said encoded codestream into a plurality of layers;
packet generating means for generating a plurality of packets from one layer to another;
error correction encoding means for applying error correction encoding to data of a header and/or a packet or packets of a predetermined one or more layers; and
embedding means for embedding an inspection symbol generated by said error correction encoding means in a main header or in a COM marker of a tile part header.

9. A picture encoding apparatus comprising:
filtering means for filtering an input picture to generate a plurality of sub-bands;
code block generating means for splitting each sub-band to generate a plurality of code blocks each being of a predetermined size;
bitplane generating means for generating a plurality of bitplanes from the most significant bit to the least significant bit, from one code block to another;
bit modeling means for executing bit modeling from one bitplane to another;
encoding pass generating means for generating an encoding pass from one bitplane to another;
arithmetic encoding means for executing arithmetic coding in the encoding pass generated by said encoding pass generating means to generate an encoded codestream;
splitting means for splitting said encoded codestream into a plurality of layers;
packet generating means for generating a plurality of packets from one layer to another;
error correction encoding means for applying error correction encoding to data of a header and/or a packet or packets of predetermined one or more layers; and
embedding means for embedding an inspection symbol generated by said error correction encoding means in a portion of a predetermined code block or in a newly added encoding pass.

10. A picture encoding method comprising:
an arithmetic encoding step of applying arithmetic encoding to an input picture to generate an encoded codestream;
a splitting step of splitting said encoded codestream into a plurality of layers;
a packet generating step of generating a plurality of packets from one layer to another;
an error correction encoding step of applying error correction encoding to data of a header and/or a packet or packets of predetermined one or more layers; and
an embedding step of embedding an inspection symbol generated by said error correction encoding step in the packets of a predetermined lower layer.

11. A picture encoding method comprising:
an arithmetic encoding step of applying arithmetic coding to an input picture to generate an encoded codestream;
a splitting step of splitting said encoded codestream into a plurality of layers;
a packet generating step of generating a plurality of packets from one layer to another;
an error correction encoding step of applying error correction encoding to data of a header and/or a packet or packets of a predetermined one or more layers; and
an embedding step of embedding an inspection symbol generated by said error correction encoding step in a main header or in a COM marker of a tile part header.

12. A picture encoding method comprising:
a filtering step of filtering an input picture to generate a plurality of sub-bands;
a code block generating step of splitting each sub-band to generate a plurality of code blocks each being of a predetermined size;
a bitplane generating step of generating a plurality of bitplanes from the most significant bit to the least significant bit, from one code block to another;
a bit modeling step of executing bit modeling from one bitplane to another;
an encoding pass generating step of generating an encoding pass from one bitplane to another;
an arithmetic encoding step of executing arithmetic coding in the encoding pass generated by said encoding pass generating step to generate an encoded codestream;
a splitting step of splitting said encoded codestream into a plurality of layers;
a packet generating step of generating a plurality of packets from one layer to another;
an error correction encoding step of applying error correction encoding to data of a header and/or a packet or packets of one or more layers; and
an embedding step of embedding an inspection symbol generated by said error correction encoding step in a portion of a predetermined code block or in a newly added encoding pass.

13. A picture decoding apparatus supplied with an encoded codestream and decoding the input encoded codestream to restore an input picture, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a packet of a predetermined lower layer, said apparatus comprising:
analysis means for analyzing said input encoded codestream;
extraction means for extracting said inspection symbol from a packet or packets of said lower layer;
error correcting decoding means for applying error correction and decoding to data of the header and/or a packet or packets of one or more preset layers, using said inspection symbol; and
decoding means for decoding the encoded codestream following the error correction and decoding.

14. The picture decoding apparatus according to claim 13 wherein said predetermined lower layer at least includes the lowermost layer.

15. The picture decoding apparatus according to claim 13 wherein said input encoded codestream has data of a packet or packets of said predetermined lower layer replaced by said inspection symbol; and
wherein said extraction means extracts said inspection symbol from a packet or packets of the lower layer, and discards the data of a packet or packets of the lower layer, or sets the data of a packet or packets of the lower layer all to zero.

16. A picture decoding apparatus supplied with an encoded codestream and decoding the input encoded codestream to restore an input picture, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol, generated on this error correction coding, in a COM marker of a main header or a tile part header, said apparatus comprising:
analysis means for analyzing said input encoded codestream;
extraction means for extracting said inspection symbol from said COM marker;
error correcting decoding means for applying error-correction and decoding to data of a header and/or a packet or packets of one or more preset layers, using said inspection symbol; and
decoding means for decoding the encoded codestream following the error correction and decoding.

17. A picture decoding apparatus supplied with an encoded codestream and decoding the input encoded codestream to restore an input picture, said encoded codestream being such a one obtained on filtering the input picture in a picture encoding apparatus to generate a plurality of sub-bands, splitting the generated sub-bands to generate a plurality of code blocks each being of a predetermined size, generating a plurality of bitplanes from the most significant bit to the least significant bit, from one code block to another; performing bit modeling from one bitplane to another to generate a plurality of encoding passes, performing arithmetic coding in the generated encoding passes to generate an encoded codestream, splitting said encoded codestream into a plurality of layers, generating a plurality of packets from one layer to another, applying error correction and encoding to data of a header and/or the packet or packets of preset one or more layers to generate an inspection symbol, and on embedding the generated inspection symbol in a portion of the preset code block or in a newly added encoding pass, said picture decoding apparatus comprising:
analysis means for analyzing said input encoded codestream;
extraction means for extracting said inspection symbol from said portion of the preset code block or in said newly added encoding pass;
error correcting decoding means for applying error correction and decoding to data of a header and/or a packet or packets of one or more preset layers, using said inspection symbol; and
decoding means for decoding the encoded codestream following the error correction and decoding.

18. A picture decoding method in which an input encoded codestream is supplied and the supplied encoded codestream is decoded to restore an input picture, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a packet of a predetermined lower layer, said method comprising:
an analysis step of analyzing said input encoded codestream;
an extraction step of extracting said inspection symbol from the packet or packets of said lower layer;
an error correcting decoding step of applying error correction and decoding to data of a header and/or a packet or packets of one or more preset layers, using said inspection symbol; and
a decoding step of decoding the encoded codestream following the error correction and decoding.

19. A picture decoding method in which an input encoded codestream is supplied and the supplied encoded codestream is decoded to restore an input picture, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a COM marker of a main header or a tile part header, said method comprising:
an analysis step of analyzing said input encoded codestream;
an extraction step of extracting said inspection symbol from said COM marker;
an error correcting decoding step of applying error correction and decoding to data of a header and/or a packet or packets of one or more preset layers, using said inspection symbol; and
a decoding step of decoding the encoded codestream following the error correction and decoding.

20. A picture decoding method in which an encoded codestream is supplied and the input encoded codestream is decoded to restore an input picture, said encoded codestream being such a one obtained on filtering an input picture in a picture encoding apparatus to generate a plurality of sub-bands, splitting the generated sub-bands to generate a plurality of code blocks each being of a predetermined size, generating a plurality of bitplanes from the most significant bit to the least significant bit, from one of said code blocks to another, performing bit modeling from one bitplane to another to generate a plurality of encoding passes, performing arithmetic coding in the generated encoding passes to generate an encoded codestream, splitting said encoded codestream into a plurality of layers, generating a plurality of packets from one layer to another, applying error correction and encoding to data of a header and/or a packet or packets of preset one or more layers, and on embedding the generated inspection symbol in a portion of the preset code block or in a newly added encoding pass; said picture decoding method comprising:
an analysis step of analyzing said input encoded codestream;
an extraction step of extracting said inspection symbol from said portion of the preset code block or in said newly added encoding pass;
an error correcting decoding step of applying error correction and decoding to data of a header and/or a packet or packets of one or more preset layers, using said inspection symbol; and
a decoding step for decoding the encoded codestream following the error correction and decoding.

21. An error correction encoding apparatus comprising:
splitting means for being supplied with an encoded codestream, generated on arithmetic coding of an input picture, and for splitting the supplied encoded codestream into a plurality of layers;
packet generating means for generating a plurality of packets from one layer to another;
error correction encoding means for applying error correction encoding to data of a header and/or a packet of a predetermined one or more layers; and
embedding means for embedding an inspection symbol generated by said error correction encoding means in the packet of a predetermined lower layer.

22. The error correction encoding apparatus according to claim 21 wherein said predetermined one or more layers includes at least the uppermost layer.

23. The error correction encoding apparatus according to claim 21 wherein said embedding means substitutes said inspection symbol for data of the packet or packets of said predetermined lower layer.

24. The error correction encoding apparatus according to claim 23 wherein, if the data volume of said inspection symbol is larger than the data volume of the packets of said predetermined lower layer, said embedding means embeds said inspection symbol across the packets of a plurality of lower layers including said predetermined lower layer.

25. The error correction encoding apparatus according to claim 21 wherein said embedding means appends said inspection symbol to data of the packet or packets of said predetermined lower layer.

26. The error correction encoding apparatus according to claim 25 wherein said embedding means changes the data length stated in a packet header of the packet or packets of said predetermined lower layer.

27. The error correction encoding apparatus according to claim 21 wherein said error correction encoding means sets the subject entity of the error correction encoding depending on the error rate of a communication channel on which said encoded codestream is transmitted.

28. An error correction encoding apparatus comprising:
splitting means for being supplied with an encoded codestream, generated on arithmetic coding of an input picture, and for splitting the supplied encoded codestream into a plurality of layers;
packet generating means for generating a plurality of packets from one layer to another;
error correction encoding means for applying error correction encoding to data of a header and/or a packet or packets of a predetermined one or more layers; and
embedding means for embedding an inspection symbol generated by said error correction encoding means in a COM marker of a main header or a tile part header.

29. An error correction encoding apparatus comprising:
splitting means for splitting an encoded codestream into a plurality of layers, said encoded codestream being such a one obtained on applying filtering to an input picture in a picture encoding apparatus to generate a plurality of sub-bands, splitting the generated sub-bands to generate a plurality of code blocks each being of a predetermined size, generating a plurality of bitplanes from the most significant bit to the least significant bit, from one of said code blocks to another, bit modeling from one bitplane to another to generate a plurality of encoding passes, and performing arithmetic coding in the generated encoding passes;
packet generating means for generating a plurality of packets from one layer to another;
error correction encoding means for applying error correction encoding to data of a header and/or a packet or packets of a predetermined one or more layers; and
embedding means for embedding an inspection symbol generated by said error correction encoding means in a portion of a predetermined code block or in a newly added encoding pass.

30. An error correction encoding method comprising:
a splitting step of being supplied with an encoded codestream, generated on arithmetic coding of an input picture, and splitting the supplied encoded codestream into a plurality of layers;
a packet generating step of generating a plurality of packets from one layer to another;
an error correction encoding step of applying error correction encoding to data of a header and/or a packet or packets of a predetermined one or more layers; and
an embedding step of embedding an inspection symbol generated by said error correction encoding step in the packet of a predetermined lower layer.

31. An error correction encoding method comprising:
a splitting step of being supplied with an encoded codestream, generated on arithmetic coding of an input picture, and splitting the supplied encoded codestream into a plurality of layers;
a packet generating step of generating a plurality of packets from one layer to another;
an error correction encoding step of applying error correction encoding to data of a header and/or a packet or packets of a predetermined one or more layers; and
an embedding step of embedding an inspection symbol generated by said error correction encoding step in a COM marker of a main header or a tile part header.

32. An error correction encoding method comprising:
a splitting step of splitting said encoded codestream into a plurality of layers, said encoded codestream being such a one obtained on filtering an input picture to generate a plurality of sub-bands, splitting the generated sub-bands to generate a plurality of code blocks each being of a predetermined size, generating a plurality of bitplanes from the most significant bit to the least significant bit, from one code block to another; performing bit modeling from one bitplane to another to generate a plurality of encoding passes, and performing arithmetic coding in the generated encoding passes;
a packet generating step of generating a plurality of packets from one layer to another;
an error correction encoding step of applying error correction encoding to data of a header and/or a packet or packets of a predetermined one or more layers; and
an embedding step of embedding an inspection symbol generated by said error correction encoding step in a portion of a predetermined code block or in a newly added encoding pass.

33. An error correction decoding apparatus supplied with an encoded codestream and decoding the input encoded codestream to restore an input picture, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in packets of a predetermined lower layer, said apparatus comprising:
an analysis means for analyzing said input encoded codestream;
an extraction means for extracting said inspection symbol from the packets of said lower layer; and
an error correcting decoding means for applying error correction and decoding to data of a header and/or the packets of one or more preset layers, using said inspection symbol.

34. The error correction decoding apparatus according to claim 33 wherein said predetermined one or more layers at least includes the uppermost layer.

35. The error correction decoding apparatus according to claim 33 wherein said input encoded codestream has data of the packets of said predetermined lower layer replaced by said inspection symbol; and
wherein said extraction means extracts said inspection symbol from the packets of the lower layer, and discards the data of the packet of the lower layer, or sets the data of the packets of the lower layer all to zero.

36. An error correction decoding apparatus supplied with an encoded codestream and decoding the input encoded codestream to restore an input picture, said encoded codestream being such a one obtained in a picture encoding apparatus on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a COM marker of a main header or a tile part header, said apparatus comprising:
analysis means for analyzing said input encoded codestream;
extraction means for extracting said inspection symbol from the packet of said COM marker; and
error correcting decoding means for applying error correction and decoding to data of a header and/or a packet of one or more preset layers, using said inspection symbol.

37. An error correction decoding apparatus supplied with an encoded codestream and decoding the input encoded codestream to restore an input picture, said encoded codestream being such a one obtained on filtering an input picture in a picture encoding apparatus to generate a plurality of sub-bands, splitting the generated sub-bands to generate a plurality of code blocks, each being of a predetermined size, generating a plurality of bitplanes, from the most significant bit to the least significant bit, from one code block to another, performing bit modeling from one bitplane to another to generate a plurality of encoding passes, performing arithmetic coding in the generated encoding pass to generate an encoded codestream, splitting said encoded codestream into a plurality of layers, generating a plurality of packets from one layer to another, applying error correction and encoding to data of a header and/or the packets of a preset one or more layers, and on embedding the generated inspection symbol in a portion of the preset code block or in a newly added encoding pass; said apparatus comprising:
analysis means for analyzing said input encoded codestream;
extraction means for extracting said inspection symbol from said portion of the preset code block or from said newly added encoding pass; and
error correcting decoding means for applying error correction and decoding to data of a header and/or a packet or packets of one or more preset layers, using said inspection symbol.

38. An error correction decoding method in which an encoded codestream is supplied and the input encoded codestream is decoded to restore an input picture, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a packet of a predetermined lower layer, said method comprising:
an analysis step of analyzing said input encoded codestream;
an extraction step of extracting said inspection symbol from the packet of said lower layer; and
an error correcting decoding step of applying error correction and decoding to data of a header and/or a packet or packets of one or more preset layers, using said inspection symbol.

39. An error correction decoding method in which an encoded codestream is supplied and the input encoded codestream is corrected for errors, said encoded codestream being such a one obtained on applying arithmetic coding to the input picture to generate an encoded codestream, splitting the encoded codestream into a plurality of layers, generating a plurality of packets from one layer to another, applying error correction coding to data of a header and/or a packet or packets of one or more preset layers, and on embedding an inspection symbol generated on this error correction coding in a COM marker of a main header or a tile part header, said method comprising:
an analysis step of analyzing said input encoded codestream;
an extraction step of extracting said inspection symbol from the packet of said lower layer; and
an error correcting decoding step of applying error correction and decoding to data of a header and/or a packet of one or more preset layers, using said inspection symbol.

40. An error correction decoding method in which an encoded codestream is supplied and the input encoded codestream is corrected for errors, said encoded codestream being such a one obtained on filtering an input picture in a picture encoding apparatus to generate a plurality of sub-bands, splitting the generated sub-bands to generate a plurality of code blocks, each being of a predetermined size, generating a plurality of bitplanes, from the most significant bit to the least significant bit, from one code block to another; performing bit modeling from one bitplane to another to generate a plurality of coding passes, performing arithmetic coding in the generated encoding passes to generate an encoded codestream, splitting said encoded codestream into a plurality of layers, generating a plurality of packets from one layer to another, applying error correction and encoding to data of a header and/or a packet or packets of preset one or more layers, and on embedding the generated inspection symbol in a portion of the preset code block or in a newly added encoding pass; said method comprising:
an analysis step of analyzing said input encoded codestream;
an extraction step of extracting said inspection symbol from said portion of the preset code block or in said newly added encoding pass; and
an error correcting decoding step of applying error correction and decoding to data of a header and/or a packet or packets of one or more preset layers, using said inspection symbol.
